(19) United States
(12) Patent Application Publication
(10) Pub. No.: US 2026/0286496 A1
(43) Pub. Date: Sep. 24, 2026

(54) A METHOD OF MANUFACTURING A COMPONENT FOR A MATRIX-ARRAY FORCE SENSOR AND ROLL-TO-ROLL APPARATUS TO CARRY OUT THE SAME

(71) Applicant: Peratech IP Ltd, North Yorkshire (GB)

(72) Inventors: Tom MITCHELL-WILLIAMS, North Yorkshire (GB); Benjamin BEDDARD, North Yorkshire (GB)

(73) Assignee: Peratech IP Ltd, North Yorkshire (GB)

(21) Appl. No.: 19/474,184

(22) PCT Filed: Apr. 8, 2024
(86) PCT No.: PCT/GB2024/050929

§ 371 Date: Oct. 9, 2025

(30) Foreign Application Priority Data
Apr. 11, 2023 (GB) 2305296.2

(51) Int. Cl. C23C 14/04; C23C 14/56; G01L 1/20; G01L 1/22; H01C 17/065

(52) U.S. Cl. CPC C23C 14/04; C23C 14/56; G01L 1/205; G01L 1/2287; H01C 17/065

(57) ABSTRACT

Examples disclosed relate to a method of manufacturing a component for a matrix-array force sensor, the method comprising: depositing a conductive material on a patterned substrate, wherein the patterned substrate comprises plateau regions and recessed grooves between the plateau regions, wherein the depositing of the conductive material covers the plateau regions to form electrodes, wherein at least the base of each groove remains uncovered by the conductive material after the depositing to define gaps between adjacent electrodes; and printing a printable material onto the electrodes to form a printed layer over each electrode.

### TECHNICAL FIELD

The present disclosure relates to a method of manufacturing a component for a matrix-array force sensor, a roll-to-roll method of manufacturing matrix-array force sensors and a roll-to-roll apparatus.

### BACKGROUND

Force sensing touchpads may be used in many devices, such as mobile telephones, tablet computers, touch sensitive trackpads and force-sensitive coatings. Users can input single or multi-touch gestures or swipes to interact with the device. Matrix-array force sensors need to accurately track the location of a force input (e.g., from a finger or stylus) and measure the force applied. The sensor array needs to have a low latency to respond quickly to the input force. Current manufacturing methods of matrix-array force sensors lack the capability of producing high resolution sensor features whilst also providing a high manufacturing throughput.

### BRIEF SUMMARY OF THE DISCLOSURE

Aspects and embodiments of the invention provide a method of manufacturing a component for a matrix-array force sensor, a roll-to-roll the method of manufacturing matrix-array force sensors and a roll-to-roll apparatus.

In accordance with the present disclosure there is provided a method of manufacturing a component for a matrix-array force sensor, the method including: depositing a conductive material on a patterned substrate, wherein the patterned substrate includes plateau regions and recessed grooves between the plateau regions, wherein the depositing of the conductive material covers the plateau regions to form electrodes, wherein at least the base of each groove remains uncovered by the conductive material after the depositing to define gaps between adjacent electrodes; and printing a printable material onto the electrodes to form a printed layer over each electrode.

The patterned substrate may further include plateau track regions and recessed track grooves between the plateau track regions, wherein the depositing of the conductive material covers the plateau track regions to form conductive tracks to electrically connect the electrodes to an external component. At least the base of each track groove remains uncovered by the conductive material after the depositing to define gaps between adjacent tracks.

The plateau track regions may be peripheral to the plateau regions.

The plateau track regions may be contiguous with corresponding plateau regions.

The printable material may be a resistive material.

The printable material may adhere to the conductive material.

The depositing of conductive material may include printing the conductive material onto the patterned substrate. The printing may be flexographic printing.

The depositing of conductive material may include a line-of-sight depositing of the conductive material, the line-of-sight depositing including deposition of the conductive material from a conductive material source positioned so the conductive material reaches the substrate from the conductive material source at an acute angle to the plane of the plateau regions of the patterned substrate. The angle may be in the range of 20 to 70 degrees.

The line-of-sight depositing of the conductive material may be performed using the conductive material source at a single position.

The depositing may include physical vapor deposition.

The ratio of the depth of the grooves to the width of the grooves may be at least 2:1. The ratio of the depth of the grooves to the width of the grooves may be at least 1.5:1. The ratio of the depth of the grooves to the width of the grooves may be at least 1:1.

The grooves may have a width no larger than 100 micrometres. The grooves may have a width in the range of 10 micrometres to 100 micrometres. The grooves may have a width no larger than 10 micrometres.

The electrodes may each include a main body portion and a plurality of projections extending from the main body portion.

The printing of the printable material may include flexographic printing.

In an aspect there is provided a roll-to-roll method of manufacturing matrix-array force sensors, the method including: providing a first patterned substrate on a roll, the first patterned substrate including plateau regions and recessed grooves between the plateau regions; depositing conductive material to form electrodes on the plateau regions of the first patterned substrate, the electrodes having a longitudinal axis extending in a first direction with respect to a longitudinal roll axis; printing a printable material onto the electrodes to form a printed layer over each electrode of the first patterned substrate; forming a first sub-assembly roll of the first patterned substrate with the deposited conductive material and the printed layer over each electrode of the first patterned substrate.

The roll-to-roll method may further include providing a second patterned substrate on a roll, the second patterned substrate including plateau regions and recessed grooves between the plateau regions; depositing conductive material to form electrodes on the plateau regions of the second patterned substrate, the electrodes having a longitudinal axis extending in a second direction with respect to a longitudinal roll axis, the second direction perpendicular to the first direction; printing a printable material onto the electrodes of the second patterned substrate to form a printed layer over each electrode of the second patterned substrate; forming a second sub-assembly roll with the second patterned substrate with the deposited conductive material and the printed layer over each electrode of the second patterned substrate; and roll to roll combining of the first sub-assembly roll with the second sub-assembly roll to form a combined roll of matrix-array force sensors.

In an aspect there is provided a roll-to-roll apparatus, including: a first roller configured to receive a first patterned substrate, the first patterned substrate including plateau regions and recessed grooves between the plateau regions; a first depositing facility configured to deposit conductive material to form electrodes on the plateau regions of the first patterned substrate, the electrodes having a longitudinal axis extending in a first direction with respect to a longitudinal roll axis; a second depositing facility configured to print a printable material onto the electrodes of the first patterned substrate to form a printed layer over each electrode of the first patterned substrate; and a first sub-assembly roller configured to receive a first sub-assembly roll of first patterned substrate with the deposited conductive material and the printed layer over each electrode of the first patterned substrate.

The roll-to-roll apparatus may further include a second roller configured to receive a second patterned substrate, the second patterned substrate including plateau regions and recessed grooves between the plateau regions; a third depositing facility configured to deposit conductive material to form electrodes on the plateau regions of the second patterned substrate, the electrodes having a longitudinal axis extending in a second direction with respect to a longitudinal roll axis, the second direction perpendicular to the first direction; a fourth depositing facility configured to print the printable material onto the electrodes of the second patterned substrate to form a printed layer over each electrode of the second patterned substrate; a second sub-assembly roller configured to receive the second patterned substrate with the deposited conductive material and the printed layer over each electrode of the second patterned substrate; and a combination roller configured to superimpose the first sub-assembly roll with the second sub-assembly roll to form a combined roll of matrix-array force sensors.

The printable material may be a resistive material.

### BRIEF DESCRIPTION OF THE DRAWINGS

Example embodiments are further described hereinafter with reference to the accompanying drawings, in which:

FIG. 1 shows a method of manufacturing a component for a matrix-array force sensor according to examples disclosed herein;

FIG. 2 shows part of a method of manufacturing a component for a matrix-array force sensor according to examples disclosed herein;

FIG. 3 shows deposition of a conductive material on a patterned substrate according to examples disclosed herein;

FIG. 4 illustrates electrodes and tracks for a matrix-array force sensor according to examples disclosed herein;

FIG. 5 illustrates parts of two electrodes for a matrix-array force sensor according to examples disclosed herein;

FIG. 6 illustrates part of a method of manufacturing a component for a matrix-array force sensor according to examples disclosed herein;

FIGS. 7A and 7B show printing a printable material onto electrodes to form a printed layer over each electrode according to examples disclosed herein;

FIG. 8 shows a roll-to-roll method of manufacturing matrix-array force sensors according to examples disclosed herein;

FIG. 9 shows part of a roll-to-roll method of manufacturing matrix-array force sensors according to examples disclosed herein;

FIG. 10 illustrates a roll-to-roll apparatus according to examples disclosed herein;

FIG. 11 illustrates a roll-to-roll apparatus according to examples disclosed herein;

FIG. 12 illustrates a roll-to-roll apparatus according to examples disclosed herein.

### DETAILED DESCRIPTION

Matrix-array force sensors with high resolution sensor features are beneficial for improving the location tracking accuracy of the matrix-array force sensor. The methods of manufacturing matrix-array force sensor components disclosed herein provide the ability to produce matrix-array force sensors with high resolution sensor features whilst also being manufacturing methods which are scalable for high throughput of manufacture, for instance using roll-to-roll (R2R) manufacturing.

Using a known printing process such as screen printing to define the shape and location of electrodes and resistive layers may be limited by screen print resolution and the requirement for accurate registration for high-resolution patterns. Ink slump from thicker wet deposits can also affect uniformity and precision of fine line features. Typical surface roughness of printed conductive inks can lead to defects in so-called “thru-mode” force sensors.

Another example process for producing matrix array force sensor components is via depositing material and then subtractive processing e.g., laser ablation. There can be, however, several disadvantages with this approach. It requires an additional processing step after material deposition to define the shape and position of electrodes and resistive layers, which is less efficient than other methods. Laser ablation is only effective at speed for specific materials which can limit this method's applicability; for example the surface of the material to be ablated cannot be too reflective. Other disadvantages include ablated material being redeposited on the surface which can cause defects, and local heat generation which can cause distortion in substrates. For high throughput of manufacture, it may also require multiple laser heads to be used, which leads to a compromise between achievable minimum resolution and cost per laser head.

Another example process for producing matrix array force sensors is lithographic patterning of individual layers. This requires multiple steps including mask deposition and removal, and is therefore inefficient for high throughput manufacturing.

Examples disclosed herein use a patterned substrate with plateau regions and recessed grooves which provides the patterning for the subsequent materials deposited and printed for use in force sensing architecture. The patterned substrate can also be referred to as a 3D relief pattern. The recessed grooves can also be referred to as micro-embossed features. In some examples, the patterned substrate can be formed via nanoimprint lithography. The plateau regions in some examples are substantially flat.

Examples disclosed herein provide a process of producing matrix-array force sensor components which are scalable for roll-to-roll (R2R) patterning, conductive material deposition and printing of printable material. The R2R substrate patterning is inherited by layers formed during subsequent depositing and printing processes to provide matrix-array force sensor components with high resolution sensor features without the need for subtractive post-processing.

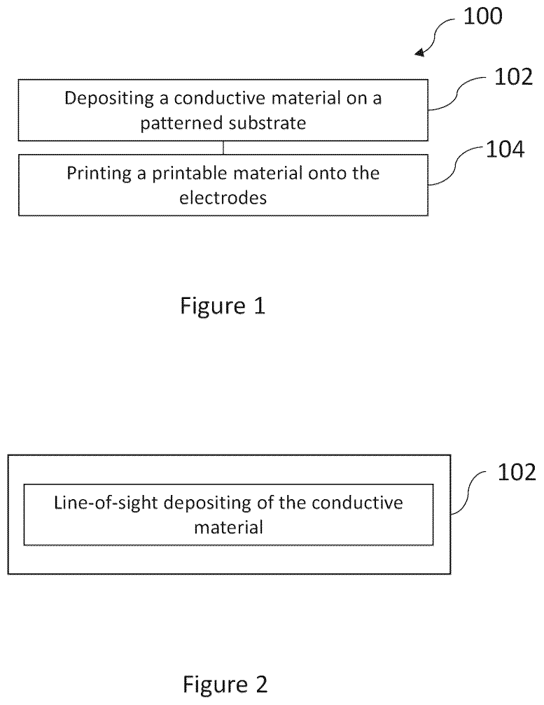

FIG. 1 shows an example method 100 of manufacturing a component for a matrix-array force sensor according to examples disclosed herein. The method 100 includes: depositing 102 a conductive material on a patterned substrate. The patterned substrate includes plateau regions and recessed grooves between the plateau regions. The depositing of the conductive material covers the plateau regions to form electrodes. At least the base of each groove remains uncovered by the conductive material after the depositing to define gaps between adjacent electrodes.

The method 100 also includes printing 104 a printable material onto the electrodes to form a printed layer over each electrode.

In some examples the patterned substrate can further include plateau track regions and recessed track grooves between the plateau track regions. The depositing 102 of the conductive material covers the plateau track regions to form conductive tracks to electrically connect the electrodes to an external component. The external component can be, for example, a controller including at least one processor(s) and memory. In some examples, the method 100 provides a component which is used to assemble a sensing module including a matrix-array force sensor and the controller. The matrix-array force sensor may include a first component made according to the method 100 and a second component made according to the method 100. The first component may provide row electrodes of the matrix-array force sensor and the second component may provide column electrodes of the matrix-array force sensor. The memory of the controller may include computer program instructions which, when executed by the one or more processor(s), cause the processor(s) to determine the location and strength of a force applied to a touch surface of the sensing module using signals detected using the first component and the second component.

In some examples, the printable material is a resistive material. The method 100 can therefore be used to provide a resistive layer over each electrode.

The sensing module including the matrix-array force sensor and the controller in some examples is configured to detect application of a force to the surface of the matrix-array force sensor by the decrease in separation distance between one of more row electrodes of the first component and one or more electrodes of the second component changing the electrical resistance at the point of force application. This change in resistance can be detected and converted into a measure of the force applied and the location of the force on the matrix array force sensor.

In the example method 100, at least the base of each track groove remains uncovered by the conductive material after the depositing 102 to define gaps between adjacent tracks.

In some examples, the printable material adheres to the conductive material, which removes the need for a separate step of adding an adhesive to the conductive material prior to the printing 104 of the printable material.

The recessed grooves act as insulating gaps between conductive regions, e.g. between adjacent electrodes and adjacent tracks. This enables a large area of conductive structure to be patterned with the recessed grooves, which act as negative regions. The resolution of the conductive structure and recessed grooves are defined by the original patterning of the substrate. In some examples, where the patterned substrate is made by a lithographic process, the recessed grooves can be produced to a resolution defined by the lithographic process (<5 micrometers) and the conductive material inherits the underlying substrate pattern without requiring high-resolution deposition or high-fidelity registration.

FIG. 2 shows part of a method 100 of manufacturing a component for a matrix-array force sensor according to examples disclosed herein.

In particular, in FIG. 2 the depositing 102 of conductive material includes a line-of-sight depositing of the conductive material. The line-of-sight depositing including deposition of the conductive material from a conductive material source positioned so the conductive material reaches the substrate from the conductive material source at an acute angle to the plane of the plateau regions of the patterned substrate. In examples, the conductive material may be a metal or alloy. Example metals include aluminium, gold, silver, copper, and titanium. Other metals, alloys or materials can be envisaged for use as the conductive material.

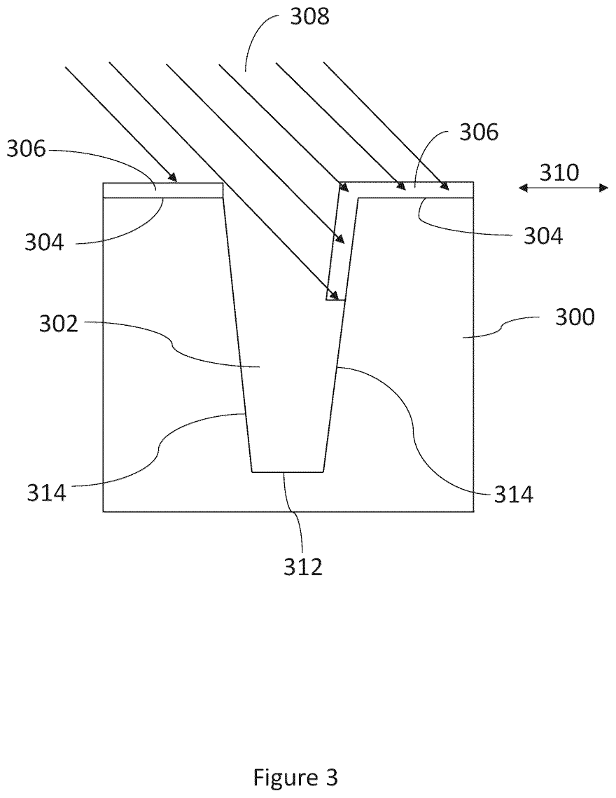

FIG. 3 shows depositing a conductive material on a patterned substrate according to examples disclosed herein. In particular, FIG. 3 illustrates an example of the line-of-sight depositing 102 of the conductive material in accordance with FIG. 2.

FIG. 3 shows part of a patterned substrate 300 according to the examples disclosed herein. One of the recessed grooves 302 is shown, with parts of two plateau regions 304 either side of the groove 302. Conductive material 306 has been deposited on the plateau regions 304 via a line-of-sight depositing technique. The arrows 308 show the direction of deposition, which is at an acute angle to the plane of the plateau regions. The arrow 310 illustrates directions which are parallel to the plane of the plateau regions. In some examples, the angle to the plane of the plateau regions is in the range of 20 to 70 degrees. It can be envisaged that other angles outside this range are possible and provide for the deposition of conductive material which allows the base of the grooves to remain free of conductive material.

The cross-section geometry of the recessed grooves 302 is provided so that subsequent line-of-sight deposition (also known as shadow deposition) of material results in conductive material only coating the exposed plateau regions 304 and limited, non-shadowed regions within the recessed grooves 302. As shown in FIG. 3, the base 312 of the recessed groove 302 and most of the sidewalls 314 of the groove 302 remain uncovered, with an upper portion (adjacent the attached plateau region 304) of the non-shadowed sidewall 314 on the right of the groove 302 being covered with the conductive material.

The ratio of the depth of the grooves 302 to the width of the grooves 302 is at least 1:1. In some preferred examples it may be at least 1.5:1, and in other preferred examples it is at least 2:1. The width of the grooves 302 may be defined as the distance between the surfaces of adjacent plateau regions 304 or adjacent plateau track regions. In some examples, as illustrated in FIG. 3, the distance between surfaces of adjacent plateau regions 304 or adjacent plateau track regions is larger than the width of the base 312 of the groove 302.

In some examples, as illustrated in FIG. 3, the line-of-sight depositing 102 of the conductive material 306 is performed using the conductive material source at a single position. In other examples, the line-of-sight depositing 102 of conductive material 306 may be performed using the conductive material source located at two positions. The second position may be at an opposite but approximately equal angle to the normal to the plane of the plateau regions 304; this deposition of conductive material from two positions may result in the upper portion of the groove 302 being approximately equally coated in conductive material on both sides 314. The line-of-sight depositing 102 of conductive material 306 performed using the conductive material source from one position may be preferred because it reduces the risk of an electrical short occurring by conductive material associated with adjacent electrodes or tracks being too close to one another, i.e. if a significant amount of conductive material is deposited on both sidewalls 314 of the groove 302.

The length of the recessed groove 302 (as shown in FIG. 3, this would be normal to the page) should preferably avoid being located parallel to the conductive material source direction as this may result in conductive material being deposited along the length of the groove 302 including the base 314, and thus possibly not leave a non-conductive gap between plateaus 304.

With angled, shadowed deposition as illustrated in FIG. 3 the recessed grooves 302 act as insulating breaks between both adjacent electrodes and adjacent tracks. This means a much higher fill fraction of conductive material (the fraction of the total area occupied by the electrodes, tracks and grooves which is filled with conductive material) can be used in both the area occupied by the electrodes (the active area) and the area occupied by the tracks (non-sensing area) than is typically achieved via other techniques e.g., screen printing. The high relative fill fraction of conductor means that line resistances and/or bezel widths can be kept low without needing a fully lithographic production process. Low line resistances are important to ensure sufficient signal-to-noise when used in force sensing resistor applications. Low bezel widths are relevant when incorporating matrix array force sensors into consumer electronics such as flexible touchscreens, by helping to reduce the need for more complex vias or plated thru-holes.

In some examples, the line-of-sight depositing 102 includes physical vapor deposition (PVD). Using a PVD process, such as evaporative coating, may be advantageous for manufacturing force sensing arrays because it enables good control of part-to-part variability in electrode sheet resistance. With suitably controlled deposition parameters it also produces metal surfaces with a low surface roughness, which is advantageous for certain examples of resistive force sensor.

Another advantage of using a patterned substrate 300 and depositing of conductive material 306 according to the methods 100 described herein, specifically for force sensing matrix-arrays, is the very fine gaps between active sensing regions. In typical screen printed designs the gaps between features is approximately 100 micrometres, to reduce the likelihood of print defects causing neighbouring areas to be inadvertently connected. With a matrix-array force sensor, made according to the example methods 100 described herein, the gaps between adjacent sensing regions can be 10× smaller (approximately<10 micrometres). This helps to ensure that non-active regions take up minimal space within the matrix array and that all force interactions activate a response, i.e., the chance of dead zones between the N×M sensing areas (“sensels”) is reduced, N being the number of rows of electrodes and M being the number of columns of electrodes. This enables high position tracking accuracy when determining touch location.

Therefore in some examples, the grooves 302 have a width no larger than 10 micrometres.

The methods 100 described herein can be used to provide matrix-array force sensors with larger gaps if there isn't a need for very fine gaps of the order of 10 micrometers. Therefore in other examples the grooves 302 may have a width in the range of 10 micrometres to 100 micrometres. In some examples the grooves 302 may have a width no larger than 100 micrometres.

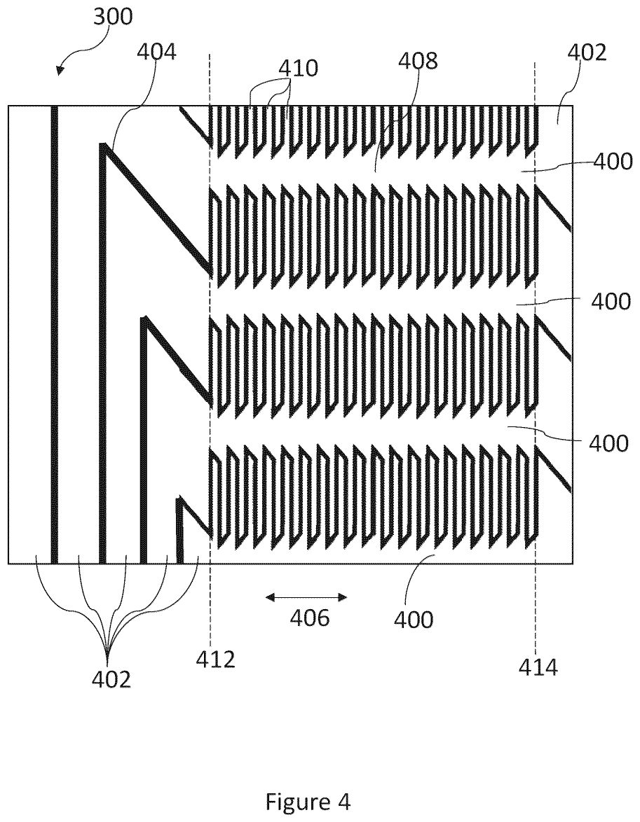

FIG. 4 illustrates electrodes and tracks for a matrix-array force sensor according to examples disclosed herein.

In particular, FIG. 4 illustrates an example portion of a patterned substrate 300, in plan view, with electrodes 400 to be utilized in a matrix-array force sensor, with connected tracks 402. The electrodes 400 and tracks 402 are defined by the recessed grooves 404. This portion of a pattern represents one layer of electrodes 400 in a matrix-array force sensor, which typically has two layers; one layer provides row electrodes and the other provides column electrodes. The example electrodes 400 shown in FIG. 4 can be, for example, row electrodes, with the rows running in the direction parallel to arrow 406. The electrodes 400 have main body portions 408 and a plurality of projections 410 projecting from each side of the electrode 400. The projections 410 of each electrode 400 are interdigitated with the projections 410 of adjacent electrodes 400.

The electrodes 400 (and therefore plateau regions underlying the electrodes 400) are between the dotted lines 412, 414 in FIG. 4 and the tracks 402 (and therefore the plateau track regions underlying the tracks 402) are to the left of dotted line 412 and to the right of dotted line 414 as shown. The precise location of the end of the plateau track regions and the plateau regions can be defined by a bezel overlying the layer of electrodes 400 in the finished matrix-array force sensor. The plateau track regions are also differentiated from the plateau regions in FIG. 4 by the main body portions 408 and projections 410 of the plateau regions.

The patterning between adjacent electrodes 400 in rows/columns as shown in FIG. 4 has two purposes: it provides a pattern of grooves 404 where none of the grooves have a length which is parallel to the direction of the deposition source, and it can be used to improve position interpolation of a force input. For example, the direction of deposition could be parallel, in one dimensional component, to the arrow 406, with the other dimensional component of the direction in a direction parallel to the normal to the plane of the patterned substrate 300.

In accordance with examples disclosed herein, the plateau track regions, which underlie the tracks 402 in FIG. 4, are peripheral to the plateau regions, which underlie the electrodes 400. In FIG. 4 the plateau track regions are shown to the left and right of the plateau regions. That is, in plan view, the plateau regions may be located centrally with the plateau track regions around the outer edge of the substrate 300. The plateau regions therefore provide a force sensor area which is bordered by tracking. In a matrix-array force sensor incorporating the electrodes 400 and tracks 402 in FIG. 4, the tracks 402 can be covered by a bezel.

In FIG. 4, the patterned substrate 300 provides both the plateau track regions and plateau regions. The plateau track regions and the plateau regions are therefore contiguous with corresponding plateau regions. In other examples the plateau track regions can be provided in a separate manufacturing step to the plateau regions.

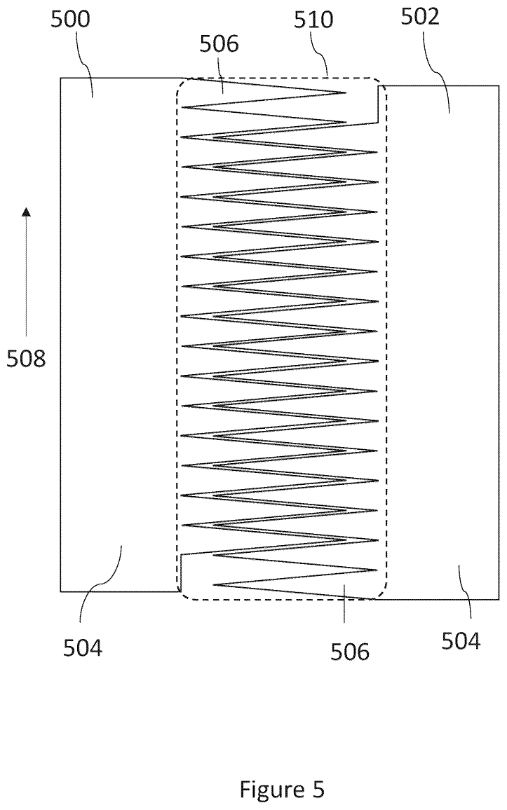

FIG. 5 illustrates parts of two electrodes 500, 502 for a component of a matrix-array force sensor according to examples disclosed herein. Each electrode 500, 502, includes a main body 504 and a plurality of projections 506, each projection 506 extending away from the main body 504. The projections 506 in this example reduce in width as they extend further away from their respective main body 504. The arrangement of electrodes 500, 502 having longitudinal axes running in a first direction 508 allows for the location of a force applied to the interpolation region 510 to be detected as a position between the first electrode 500 and the second electrode 502. That is, the position of an applied force in the two dimensional plane of the electrode layer surface may be determined in one dimension. In order to determine the position of an applied force in the two dimensional plane of the electrode layer surface in two dimensions, a second layer may be arranged on top of (i.e. superimposed on) a first layer to form a sandwich structure with the a resistive layer between the two electrode layers, wherein the longitudinal direction of the electrodes in the two layers is different. For ease of calculation of the force position, the longitudinal direction of the electrodes in the two layers may be orthogonal (i.e. the electrodes in the first electrode layer are oriented at 90 degrees to the electrodes in the second electrode layer). In this way, the location of the force may be detected in a first direction from one electrode layer, and in a second direction from the other electrode layer, allowing for the force position to be determined in two dimensions. The precision of the methods 100 disclosed herein therefore enable the production of different designs of electrodes by enabling features such as interdigitated projection portions to be easily fabricated.

The projections 506 in this example may be described as triangular or zig-zag in shape, and have a continuously varying (decreasing) size as the distance from the electrode main body 504 decreases. It will be appreciated that there are other shapes of projection 506 which may be used which also provide the functionality of allowing for the position of a force applied between in the interpolation region 510 to be determined due to a variation in the shape of the projections 506. For example, the projections 506 may have at least partially curved sides. As another example, the projections 506 may taper to a point at the projection ends (opposite to the part of the projection 506 connected to the main body 504, but may have parallel sides between the tapering portion and the main body 504. In some examples, each one of the plurality of projections 506 of the plurality of row electrodes and/or each one of the plurality of projections of the plurality of column electrodes may include at least one sub-projection, wherein each sub-projection projects away from its corresponding projection; the projections may therefore have a dendritic shape in some examples. Other projection shapes may be envisaged.

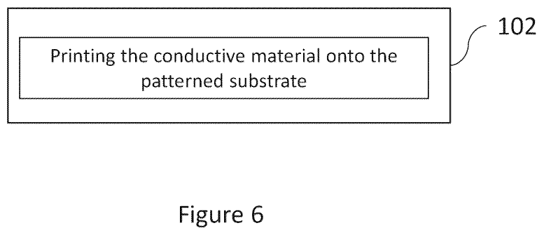

FIG. 6 illustrates part of a method 100 of manufacturing a component for a matrix-array force sensor according to examples disclosed herein. In particular in some examples, the depositing 102 of conductive material includes printing the conductive material onto the patterned substrate 300 instead of other methods of depositing such as the line-of-sight depositing according to examples described herein. In some examples the printing is flexographic printing. Flexographic printing is a process scalable to high throughput manufacturing. The conductive material printed onto the patterned substrate 300 inherits the underlying pattern of the patterned substrate 300 leading to high resolution sensor features.

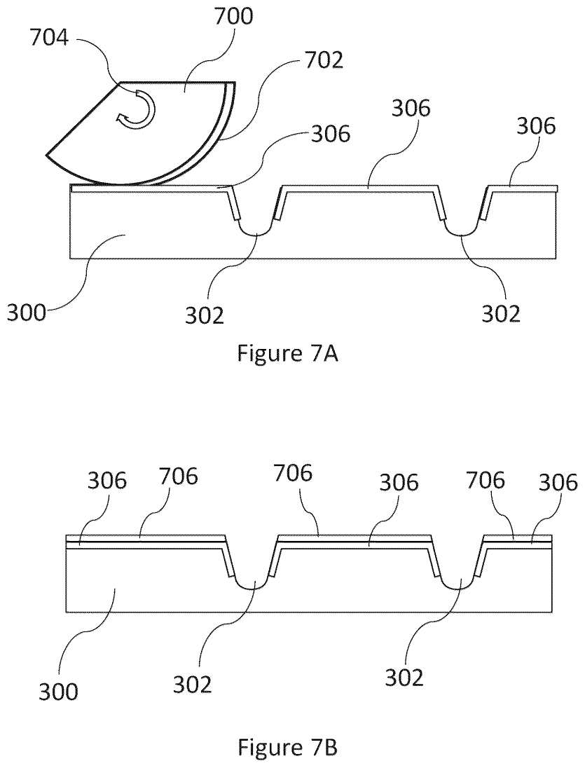

FIGS. 7A and 7B show printing 104 a printable material onto electrodes to form a printed layer over each electrode according to examples disclosed herein. In particular, in FIGS. 7A and 7B, the printing 104 includes flexographic printing.

In FIG. 7A, a flexographic roller 700 (partly shown) with the printable material 702 on its surface is rolled over the patterned substrate 300, with the direction of rotation illustrated by arrow 704. The printable material 702 will only be transferred to the raised portions of the substrate 300, which are the plateau regions and plateau track regions with the deposited conductive material 306 in this example. Hence, the patterning of the substrate 300 is advantageously inherited by the printed layers 706, as shown in FIG. 7B without requiring a high-resolution or precise registration deposition technique.

It is to be envisaged, in examples where the patterned substrate 300 includes plateau track regions and recessed track grooves, that the printable material may be printed on the conductive material 306 in the plateau regions, and not on the conductive material 306 in the plateau track regions. For example, where the printing includes flexographic printing, the flexographic roller 700 may be passed over the conductive material 306 over the plateau regions and not over the conductive material 306 in the plateau track regions. In such examples, the printable material may be resistive material as described in examples disclosed herein.

It can be seen in FIGS. 7A and 7B that the line-of-sight depositing 102 was completed using the source of conductive material at two positions, as conductive material 306 is present of both sidewalls of the recessed grooves 302. In other examples the conductive material may have been deposited from a single source position.

The printed layers 706 may be formulated as printable inks when used in film-based pressure/force sensors, if a deposition process such as R2R flexographic printing is used.

An advantage of the 3D patterned substrate 300 is that the structure defines the pattern of the electrodes, the tracks and the printed layers 706 over each electrode. The registration between the layers is therefore accomplished entirely by the substrate 300 without requiring the use of complex registration or alignment techniques.

The printed layers 706 of printable material 702 over each electrode can be a resistive material so that the printable layers 706 provide an resistive layer over each electrode. The resistive layer can have several different properties or functions, to provide functional resistive layers.

Functionality of the functional resistive layer in addition to being “resistive” may preferably include one or more of the following properties: the bulk resistivity of the material is within specific limits to achieve the force dependent change in contact resistance suitable for the application of the sensor; the surface roughness or surface texture should be well controlled and suitable for the application of the sensor; the material should be stable to temperature fluctuations that are relevant for the application of the final sensor (for example, <5% change in the bulk resistivity when tested at 85 C vs 20 C); the material should be mechanically robust enough the accommodate durability testing with a cyclic load (for example, 5 million cycles with <10% relative change in measured properties); and the material should be mechanically robust/compliant enough to accommodate any bending or stretching stresses that might occur during assembly, integration or during use of the sensor.

The functional resistive layer can include, for example a quantum tunnelling material. A quantum tunnelling material is a material which exhibits a change in electrical resistance in response to a change in force or pressure applied. Quantum tunnelling materials of this type are available from the present applicant, Peratech Holdco Limited, Brompton-on-Swale, United Kingdom under the registered trade mark QTC®.

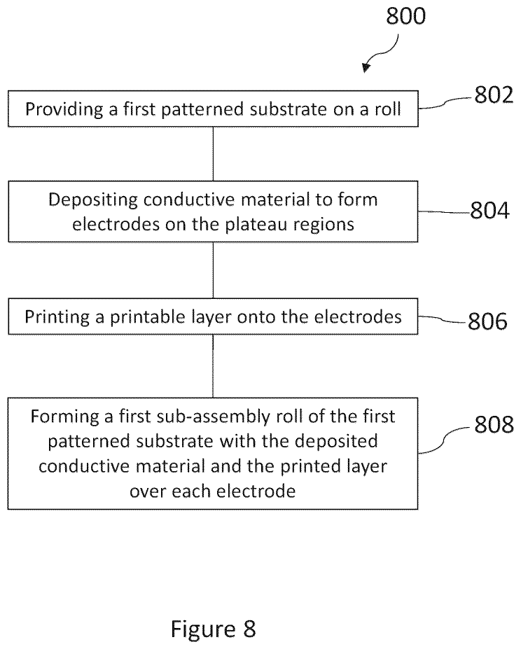

FIG. 8 shows a roll-to-roll method 800 of manufacturing matrix-array force sensors according to examples disclosed herein.

The method 800 includes providing 802 a first patterned substrate on a roll, the first patterned substrate including plateau regions and recessed grooves between the plateau regions.

The method includes depositing 804 conductive material to form electrodes on the plateau regions of the first patterned substrate, the electrodes having a longitudinal axis extending in a first direction with respect to a longitudinal roll axis.

The method also includes printing 806 a printable material onto the electrodes to form a printed layer over each electrode of the first patterned substrate.

The method also includes forming 808 a first sub-assembly roll of the first patterned substrate with the deposited conductive material and the printed layer over each electrode of the first patterned substrate.

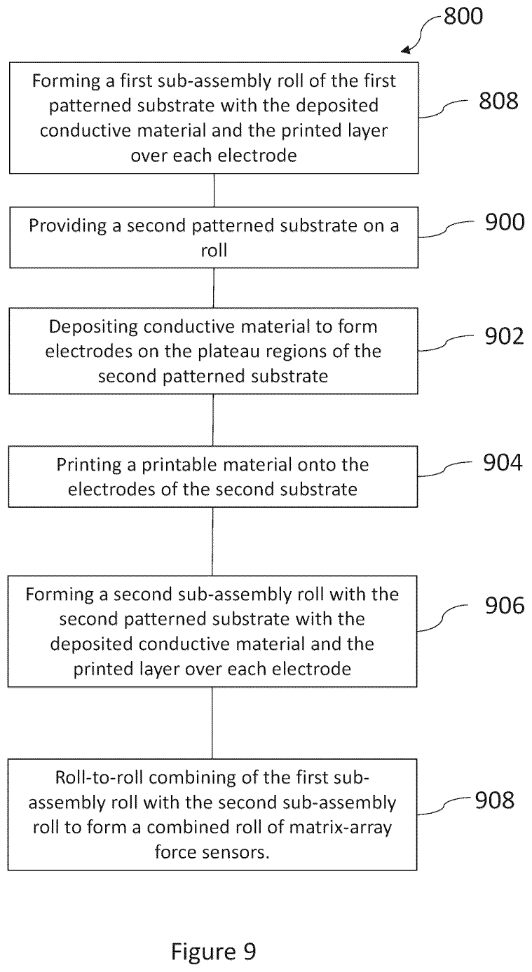

FIG. 9 shows part of a roll-to-roll method 800 of manufacturing matrix-array force sensors according to examples disclosed herein. The roll-to-roll method 800 can further include providing 900 a second patterned substrate on a roll, the second patterned substrate including plateau regions and recessed grooves between the plateau regions.

The method 800 can also include depositing 902 conductive material to form electrodes on the plateau regions of the second patterned substrate, the electrodes having a longitudinal axis extending in a second direction with respect to a longitudinal roll axis, the second direction perpendicular to the first direction.

The method 800 can also include printing 904 a printable material onto the electrodes of the second patterned substrate to form a printed layer over each electrode of the second patterned substrate.

The method 800 can also include forming a second sub-assembly roll with the second patterned substrate with the deposited conductive material and the printed layer over each electrode of the second patterned substrate.

The method can also include roll to roll combining 908 of the first sub-assembly roll with the second sub-assembly roll to form a combined roll of matrix-array force sensors.

The method 800 therefore provides an example of the method 100 of manufacturing at least one matrix-array force sensor component, specifically implemented as a roll-to-roll method. The method 800 can therefore incorporate any of the features disclosed herein in the examples of method 100. For example, the first and/or second patterned substrate can further include plateau track regions and recessed track grooves between the plateau track regions. The depositing 804, 902 of the conductive material covers the plateau track regions to form conductive tracks to electrically connect the electrodes to an external component. In some examples, The first and/or second patterned substrate can be formed via nanoimprint lithography

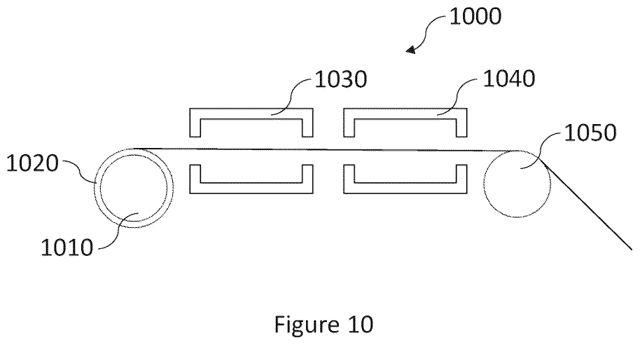

FIG. 10 illustrates a roll-to-roll apparatus 1000 according to examples disclosed herein. The roll-to-roll apparatus 1000 includes a first roller 1010 configured to receive a first patterned substrate 1020, the first patterned substrate including plateau regions and recessed grooves between the plateau regions.

The apparatus also includes a first depositing facility 1030 configured to deposit conductive material 306 to form electrodes on the plateau regions of the first patterned substrate, the electrodes having a longitudinal axis extending in a first direction with respect to a longitudinal roll axis, the roll axis being that of rollers 1010, 1050. The first depositing facility 1020 can be, for example, a flexographic printing facility, or a line-of-sight depositing facility.

The apparatus 1000 also includes a second depositing facility 1040 configured to print a printable material onto the electrodes of the first patterned substrate to form a printed layer over each electrode. For example the second depositing facility 1040 can be a flexographic printing facility. The apparatus also includes a first sub-assembly roller 1050 configured to receive a first sub-assembly roll of first patterned substrate with the deposited conductive material and the printed layer over each electrode of the first patterned substrate.

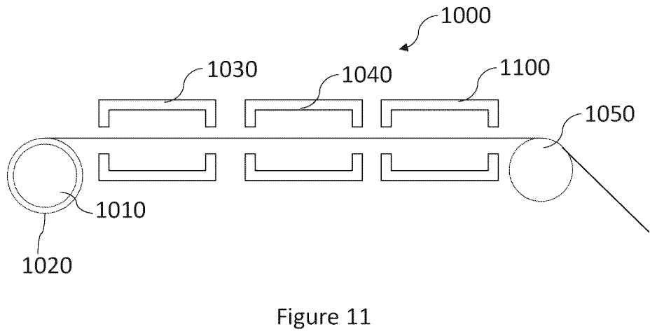

FIG. 11 illustrates a roll-to-roll apparatus 1000 according to examples disclosed herein. In this example, the apparatus 1000 also includes an adhesive depositing facility 1100. The adhesive depositing facility is configured to deposit adhesive in suitable regions of the first patterned substrate. For example the adhesive may be deposited over the plateau track regions. For example the adhesive may be deposited in an area peripheral to the plateau regions and recessed grooves. The adhesive is for bonding the first patterned substrate to a second patterned substrate to form a matrix-array force sensor.

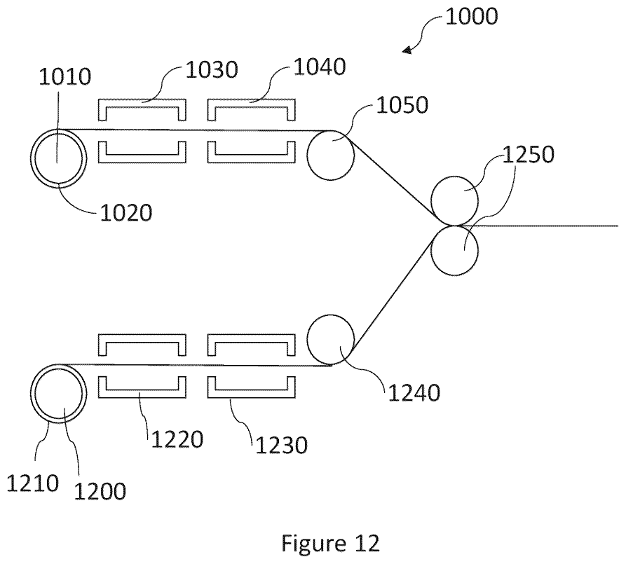

FIG. 12 illustrates a roll-to-roll apparatus 1000 according to examples disclosed herein. In this example, the apparatus 1000 also includes a second roller 1200 configured to receive a second patterned substrate 1210, the second patterned substrate including plateau regions and recessed grooves between the plateau regions.

The apparatus in FIG. 12 also includes a third depositing facility 1220 configured to deposit conductive material to form electrodes on the plateau regions of the second patterned substrate, the electrodes having a longitudinal axis extending in a second direction with respect to a longitudinal roll axis, the second direction perpendicular to the first direction. The third depositing facility 1220 can be, for example, a flexographic printing facility, or a line-of-sight depositing facility.

The apparatus 1000 in FIG. 12 also includes a fourth depositing facility 1230 configured to print a printable material onto the electrodes of the second patterned substrate to form a printed layer over each electrode of the second patterned substrate.

The apparatus 1000 in FIG. 12 also includes a second sub-assembly roller 1240 configured to receive the second patterned substrate with the deposited conductive material and the printed layer over each electrode of the second patterned substrate.

The apparatus 1000 in FIG. 12 also includes a combination roller 1250 configured to superimpose the first sub-assembly roll with the second sub-assembly roll to form a combined roll of matrix-array force sensors. The combination roller 1250 in this example presses the first sub-assembly roll with the second sub-assembly roll to form the combined roll. In accordance with the example in FIG. 11, an adhesive depositing facility 1100 can be provided in the apparatus 1000 of FIG. 12 to deposit adhesive on one or both of the first sub-assembly roll and the second sub-assembly roll to bond the first sub-assembly roll and the second sub-assembly roll. The electrode orientation of electrodes (e.g. row electrodes) on the first sub assembly roll 1050 may be perpendicular to (or at least non-parallel to) the electrode orientation of electrodes (e.g. column electrodes) on the second sub assembly roll 1240.

The example roll-to-roll apparatus 1000 described herein provide examples apparatus which perform the methods 100 of manufacturing at least one matrix-array force sensor component and the roll-to-roll methods 800 described herein. The apparatus 1000 can therefore incorporate any of the features disclosed herein in the examples of the methods 100, 800. For example, the first and/or second patterned substrate can further include plateau track regions and recessed track grooves between the plateau track regions. The depositing of the conductive material covers the plateau track regions to form conductive tracks to electrically connect the electrodes to an external component. In some examples, The first and/or second patterned substrate can be formed via nanoimprint lithography.

In the examples of FIGS. 10,11 and 12 the first patterned substrate 1020 is a roll, and has already been formed by a previous process. In other examples, the roll-to-roll apparatus can include facilities to manufacture the first patterned substrate 1020 (and/or the second patterned substrate). For example the roll-to-roll apparatus can include facilities for nanoimprint lithography for forming the first and/or second patterned substrate 1020, 1210.

The methods 100, 800 and apparatus 1000 described herein remove registration problems between electrode and restive layers during deposition, which is important for the fabrication of matrix array force sensors having fine (e.g. sub 100 micrometer) resolution features.

The methods 100, 800 and apparatus 1000 described herein provide high resolution patterning of both electrode and resistive material, which is possible through patterning the substrate. This is important for producing designs of matrix-array force sensors suitable for high resolution matrix sensor position tracking.

The methods 100, 800 and apparatus 1000 described herein do not require separate track and electrode deposition, as the electrode material is suitable for both and can be done in one manufacturing step.

The methods 100, 800 and apparatus 1000 described herein help to avoid shorting defects via inherently smooth PVD electrode material, in examples where PVD is used.

The methods 100, 800 and apparatus 1000 described herein provide high volume throughput by enabling R2R processes and industry standard deposition equipment to be used.

The methods 100, 800 and apparatus 1000 described herein provide pattern resolution which is achieved through substrate patterning in a single, industrially proven, step. Subsequent materials deposition do not require high-resolution or precise registration techniques.

The methods 100, 800 and apparatus 1000 described herein are advantageous because electrode deposition naturally fits with PVD techniques, which provide a low surface roughness and avoids potential force sensor defects.

The methods 100, 800 and apparatus 1000 described herein are advantageous because they provide processes which are efficient with material, as they do not need to remove deposited material.

The methods 100, 800 and apparatus 1000 described herein can be deployed using existing R2R, high-throughput equipment.

The methods 100 and apparatus 1000 described herein can provide functional resistive layers which can be deposited under atmospheric conditions, it does not require vacuum processing for every step.

Throughout the description and claims of this specification, the words “comprise”, “include”, and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

It will be appreciated that various changes and modifications can be made to the present invention without departing from the scope of the present application.

1. A method of manufacturing a component for a matrix-array force sensor, the method comprising:
depositing a conductive material on a patterned substrate, wherein the patterned substrate comprises plateau regions and recessed grooves between the plateau regions, wherein the depositing of the conductive material covers the plateau regions to form electrodes, wherein at least the base of each groove remains uncovered by the conductive material after the depositing to define gaps between adjacent electrodes; and
printing a printable material onto the electrodes to form a printed layer over each electrode.

2. The method of claim 1, wherein the patterned substrate further comprises plateau track regions and recessed track grooves between the plateau track regions, wherein the depositing of the conductive material covers the plateau track regions to form conductive tracks to electrically connect the electrodes to an external component, and wherein at least the base of each track groove remains uncovered by the conductive material after the depositing to define gaps between adjacent tracks.

3. The method of claim 2, wherein the plateau track regions are peripheral to the plateau regions.

4. The method of claim 2 or claim 3, wherein the plateau track regions are contiguous with corresponding plateau regions.

5. The method of any preceding claim, wherein the printable material is a resistive material.

6. The method of any preceding claim, wherein the printable material adheres to the conductive material.

7. The method of any preceding claim, wherein the depositing of conductive material comprises printing the conductive material onto the patterned substrate.

8. The method of claim 7, wherein the printing is flexographic printing.

9. The method of any of claims 1 to 6, wherein the depositing of conductive material comprises a line-of-sight depositing of the conductive material, the line-of-sight depositing comprising deposition of the conductive material from a conductive material source positioned so the conductive material reaches the substrate from the conductive material source at an acute angle to the plane of the plateau regions of the patterned substrate.

10. The method of claim 9, wherein the angle is in the range of 20 to 70 degrees

11. The method of claim 9 or claim 10, wherein the line-of-sight depositing of the conductive material is performed using the conductive material source at a single position.

12. The method of any of claims 9 to 11, wherein the depositing comprises physical vapor deposition.

13. The method of any preceding claim, wherein the ratio of the depth of the grooves to the width of the grooves is at least 2:1.

14. The method of any preceding claim, wherein the ratio of the depth of the grooves to the width of the grooves is at least 1.5:1.

15. The method any preceding claim, wherein the ratio of the depth of the grooves to the width of the grooves is at least 1:1.

16. The method of any preceding claim, wherein the grooves have a width no larger than 100 micrometres.

17. The method of any preceding claim, wherein the grooves have a width in the range of 10 micrometres to 100 micrometres.

18. The method of any preceding claim, wherein the grooves have a width no larger than 10 micrometres.

19. The method of any preceding claim, wherein the electrodes each comprise a main body portion and a plurality of projections extending from the main body portion.

20. The method of any preceding claim, wherein the printing of the printable material comprises flexographic printing.

21. A roll-to-roll method of manufacturing matrix-array force sensors, the method comprising:
providing a first patterned substrate on a roll, the first patterned substrate comprising plateau regions and recessed grooves between the plateau regions;
depositing conductive material to form electrodes on the plateau regions of the first patterned substrate, the electrodes having a longitudinal axis extending in a first direction with respect to a longitudinal roll axis;
printing a printable material onto the electrodes to form a printed layer over each electrode of the first patterned substrate;
forming a first sub-assembly roll of the first patterned substrate with the deposited conductive material and the printed layer over each electrode of the first patterned substrate.

22. The roll-to-roll method of manufacturing matrix-array force sensors of claim 21, the method further comprising:
providing a second patterned substrate on a roll, the second patterned substrate comprising plateau regions and recessed grooves between the plateau regions;
depositing conductive material to form electrodes on the plateau regions of the second patterned substrate, the electrodes having a longitudinal axis extending in a second direction with respect to a longitudinal roll axis, the second direction perpendicular to the first direction;
printing a printable material onto the electrodes of the second patterned substrate to form a printed layer over each electrode of the second patterned substrate;
forming a second sub-assembly roll with the second patterned substrate with the deposited conductive material and the printed layer over each electrode of the second patterned substrate; and
roll to roll combining of the first sub-assembly roll with the second sub-assembly roll to form a combined roll of matrix-array force sensors.

23. A roll-to-roll apparatus, comprising:
a first roller configured to receive a first patterned substrate, the first patterned substrate comprising plateau regions and recessed grooves between the plateau regions;
a first depositing facility configured to deposit conductive material to form electrodes on the plateau regions of the first patterned substrate, the electrodes having a longitudinal axis extending in a first direction with respect to a longitudinal roll axis;
a second depositing facility configured to print a printable material onto the electrodes of the first patterned substrate to form a printed layer over each electrode of the first patterned substrate; and
a first sub-assembly roller configured to receive a first sub-assembly roll of first patterned substrate with the deposited conductive material and the printed layer over each electrode of the first patterned substrate.

24. The roll-to-roll apparatus of claim 23, further comprising
a second roller configured to receive a second patterned substrate, the second patterned substrate comprising plateau regions and recessed grooves between the plateau regions;
a third depositing facility configured to deposit conductive material to form electrodes on the plateau regions of the second patterned substrate, the electrodes having a longitudinal axis extending in a second direction with respect to a longitudinal roll axis, the second direction perpendicular to the first direction;
a fourth depositing facility configured to print the printable material onto the electrodes of the second patterned substrate to form a printed layer over each electrode of the second patterned substrate;
a second sub-assembly roller configured to receive the second patterned substrate with the deposited conductive material and the printed layer over each electrode of the second patterned substrate; and
a combination roller configured to superimpose the first sub-assembly roll with the second sub-assembly roll to form a combined roll of matrix-array force sensors.

25. A roll-to-roll apparatus as claimed in claim 23 or 24, wherein the printable material is a resistive material.
